(19) United States
(12) Patent Application Publication
(10) Pub. No.: US 2026/0047305 A1
(43) Pub. Date: Feb. 12, 2026

(54) DISPLAY DEVICE

(71) Applicant: Samsung Display Co., Ltd., Yongin-si (KR)

(72) Inventors: Seon Uk LEE, Yongin-si (KR); Kang Uk KIM, Yongin-si (KR); KWANG-MIN LEE, Yongin-si (KR); Che Ho LIM, Yongin-si (KR); Kang Soo HAN, Yongin-si (KR)

(21) Appl. No.: 19/177,280

(22) Filed: Apr. 11, 2025

(30) Foreign Application Priority Data
Aug. 9, 2024 (KR) 10-2024-0106758

(51) Int. Cl. H10K 59/38; H10K 59/127; H10K 59/80

(52) U.S. Cl. CPC H10K 59/38; H10K 59/127; H10K 59/8723; H10K 59/873

(57) ABSTRACT

A display device includes a first substrate; a transistor on the first substrate; a light emitting element electrically connected to the transistor; an encapsulation layer on the light emitting element; a second substrate overlapping the first substrate; a first partition wall between the encapsulation layer and the second substrate and having a first opening, a second opening, a third opening, and a fourth opening; a first color conversion layer within the first opening; a second color conversion layer within the second opening; a transmission layer within the third opening; a column spacer within the fourth opening; and a second partition wall within the fourth opening, wherein an upper surface of the first partition wall has lyophobic properties, and an upper surface of the second partition wall has lyophilic properties.

### CROSS-REFERENCE TO RELATED APPLICATION

The present application claims priority to and the benefit of Korean Patent Application No. 10-2024-0106758, filed on Aug. 9, 2024, in the Korean Intellectual Property Office, the entire disclosure of which is incorporated herein by reference.

### BACKGROUND

### 1. Field

Aspects of the present disclosure relate to a display device.

### 2. Description of the Related Art

A light emitting element is an element in which holes supplied from an anode and electrons supplied from a cathode are combined in a light emitting layer formed between the anode and the cathode to form excitons, and light is emitted while the excitons are stabilized.

The light emitting element has several merits such as a wide viewing angle, a fast response speed, a thin thickness, and low power consumption such that the light emitting diode is widely applied to various suitable electrical and electronic devices such as televisions, monitors, mobile phones, and the like.

Recently, in order to realize a high-efficiency display device, a display device including a color conversion layer has been proposed. The color conversion layer may convert incident light into light of a different color.

The above information disclosed in this Background section is only for enhancement of understanding of the background of the invention and therefore it may contain information that does not form.

### SUMMARY

Aspects of embodiments of the present disclosure are directed to a display device that may reduce the time required for the manufacturing process and improve reliability.

According to some embodiments of the present disclosure, there is provided a display device including: a first substrate; a transistor on the first substrate; a light emitting element electrically connected to the transistor; an encapsulation layer on the light emitting element; a second substrate overlapping the first substrate; a first partition wall between the encapsulation layer and the second substrate and having a first opening, a second opening, a third opening, and a fourth opening; a first color conversion layer within the first opening; a second color conversion layer within the second opening; a transmission layer within the third opening; a column spacer within the fourth opening; and a second partition wall within the fourth opening, wherein an upper surface of the first partition wall has lyophobic properties, and an upper surface of the second partition wall has lyophilic properties.

In some embodiments, the second partition wall is surrounded by the first partition wall.

In some embodiments, the column spacer is in direct contact with an upper surface and a side surface of the second partition wall.

In some embodiments, the column spacer and the transmission layer include a same material.

In some embodiments, the display device further includes: a first color filter overlapping the first color conversion layer; a second color filter overlapping the second color conversion layer; and a third color filter overlapping the transmission layer.

In some embodiments, the column spacer overlaps the first color filter, the second color filter, and the third color filter.

In some embodiments, the display device further includes: a low-refractive index layer between the first color filter and the first color conversion layer.

In some embodiments, the display device further includes: a capping layer between the column spacer and the encapsulation layer; and a filling layer between the capping layer and the encapsulation layer.

In some embodiments, the first partition wall further includes a fifth opening, and the fifth opening is filled with the filling layer.

In some embodiments, in the fifth opening, the capping layer is in direct contact with a side surface of the first partition wall.

According to some embodiments of the present disclosure, there is provided a display device including: a first substrate; a transistor on the first substrate; a light emitting element electrically connected to the transistor; an encapsulation layer on the light emitting element; a second substrate overlapping the first substrate; a first partition wall between the encapsulation layer and the second substrate and having a first opening, a second opening, a third opening, and a fourth opening; a first color conversion layer within the first opening; a second color conversion layer within the second opening; a transmission layer within the third opening; a second partition wall integrally formed with the first partition wall; and a column spacer on the second partition wall, wherein an upper surface of the first partition wall has lyophobic properties, and an upper surface of the second partition wall has lyophilic properties.

In some embodiments, the second partition wall is surrounded by the first partition wall.

In some embodiments, the column spacer and the transmission layer include a same material.

In some embodiments, the display device further includes: a first color filter overlapping the first color conversion layer; a second color filter overlapping the second color conversion layer; and a third color filter overlapping the transmission layer, wherein the column spacer overlaps the first color filter, the second color filter, and the third color filter.

According to some embodiments of the present disclosure, there is provided a display device including: a first substrate; a transistor on the first substrate; a light emitting element electrically connected to the transistor; an encapsulation layer on the light emitting element; a second substrate overlapping the first substrate; a first partition wall between the encapsulation layer and the second substrate and having a first opening, a second opening, and a third opening; a first color conversion layer within the first opening; a second color conversion layer within the second opening; a transmission layer within the third opening; a second partition wall integrally formed with the first partition wall and including a fifth opening; and a column spacer within the fifth opening, wherein an upper surface of the first partition wall has lyophobic properties, and an upper surface of the second partition wall has lyophilic properties.

In some embodiments, the second partition wall is surrounded by the first partition wall.

In some embodiments, the column spacer and the transmission layer include a same material.

In some embodiments, the display device further includes: a first color filter overlapping the first color conversion layer; a second color filter overlapping the second color conversion layer; and a third color filter overlapping the transmission layer, wherein the column spacer overlaps the first color filter, the second color filter, and the third color filter.

In some embodiments, a content of fluorine groups included in the upper surface of the first partition wall is greater than a content of fluorine groups included in the upper surface of the second partition wall.

In some embodiments, a height of the first partition wall and a height of the second partition wall are the same.

According to some embodiments, it is possible to provide a display device that may reduce the time required for the manufacturing process and may improve reliability.

The above information disclosed in this Background section is only for enhancement of understanding of the background of the invention and therefore it may contain information that does not form.

### BRIEF DESCRIPTION OF THE DRAWINGS

FIG. 1 is a schematic exploded perspective view of a display device according to some embodiments of the present disclosure.

FIG. 2 is a schematic cross-sectional view of a display panel according to some embodiments of the present disclosure.

FIG. 3 is a plan view of some pixels in a display panel according to some embodiments of the present disclosure.

FIGS. 4 to 6 are each a cross-sectional view of a partial area of a display panel, according to some embodiments of the present disclosure.

FIG. 7 is a top plan view of a display panel according to some embodiments of the present disclosure.

FIG. 8 is a cross-sectional view of a display panel according to some embodiments of the present disclosure.

FIG. 9 is a top plan view of a display panel according to some embodiments of the present disclosure.

FIG. 10 is a cross-sectional view of a display panel according to some embodiments of the present disclosure.

FIGS. 11 to 17 are cross-sectional views of a color conversion portion according to a manufacturing process of some embodiments of the present disclosure.

FIGS. 18A-18E are images of evaluating lyophobic properties according to changes in slit and spacer widths, according to some embodiments of the present disclosure.

FIG. 19 is a block diagram of an electronic device according to some embodiments of the present disclosure.

FIG. 20 illustrates schematic diagrams of electronic devices according to various embodiments of the present disclosure.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

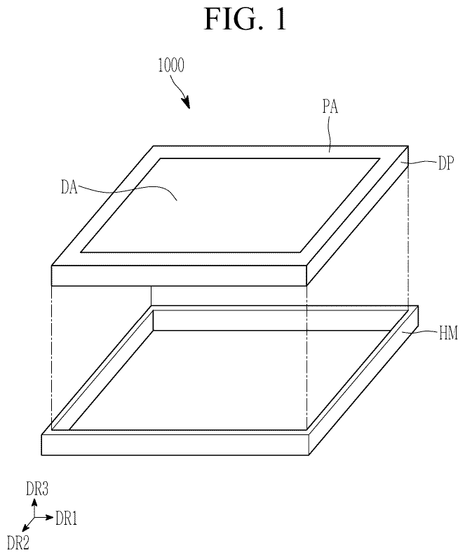

Hereinafter, a display device according to some embodiments will be described with reference to FIG. 1. FIG. 1 illustrates a schematic exploded perspective view of a display device according to some embodiments of the present disclosure.

Referring to FIG. 1, a display device 1000 according to some embodiments may include a display panel DP and a housing HM.

One surface of the display panel DP on which an image is displayed is parallel to a surface defined by a first direction DR1 and a second direction DR2. A third direction DR3 indicates a normal direction of the surface on which the image is displayed—that is, a thickness direction of the display panel DP. A front surface (or upper surface) and a back surface (or lower surface) of each member are defined along the third direction DR3. However, directions indicated by the first to third directions DR1, DR2, and DR3 are relative concepts, and thus they may be changed into other directions.

The display panel DP may be a flat rigid display panel, but is not limited thereto, and may, for example, be a flexible display panel. The display panel DP may be formed of an organic light emitting display panel. However, the type of the display panel DP is not limited thereto, and the display panel may be formed as various suitable types of panels. For example, the display panel DP may be formed as a liquid crystal panel, an electrophoretic display panel, an electrowetting display panel, or the like. In addition, the display panel DP may be made of a next-generation display panel such as a micro-light emitting diode display panel, a quantum-dot light emitting diode display panel, a quantum dot organic light emitting diode display panel, or the like.

The micro-light emitting diode (micro-LED) display panel is configured in a method in which light-emitting diodes of about 10 micrometers to about 100 micrometers in size configure each pixel. The micro-light emitting diode display panel uses inorganic materials, can omit backlighting, has a fast reaction speed, may implement high brightness with low power, and is not broken when bent, among other features.

The quantum dot light emitting diode display panel is formed by attaching a film including quantum dots or using a material including quantum dots. The quantum dots refer to particles that are made of inorganic materials such as indium and cadmium, emit light by themselves, and have a diameter of several nanometers or less. By controlling a particle size of the quantum dots, light of a desired color may be displayed. The quantum dot organic light emitting diode display panel has a structure in which a blue organic light emitting diode is used as a light source, and a film including red and green quantum dots is attached thereon, or a material including red and green quantum dots is deposited to realize color. The display panel DP according to some embodiments may be configured as various other display panels.

As shown in FIG. 1, the display panel DP includes a display area DA in which an image is displayed, and a non-display area PA adjacent to the display area DA. The non-display area PA is an area in which no image is displayed (e.g., no image is capable of being displayed). The display area DA may have, for example, a quadrangular shape, and the non-display area PA may have a suitable shape surrounding the display area DA. However, the present disclosure is not limited thereto, and the shapes of the display area DA and the non-display area PA may be relatively designed in any suitable manner.

The housing HM provides an inner space (e.g., internal space). The display panel DP is mounted inside the housing HM. In addition to the display panel DP, various suitable electronic components—for example, a power supply part, a storage device, and an audio input/output module—may be mounted inside the housing HM.

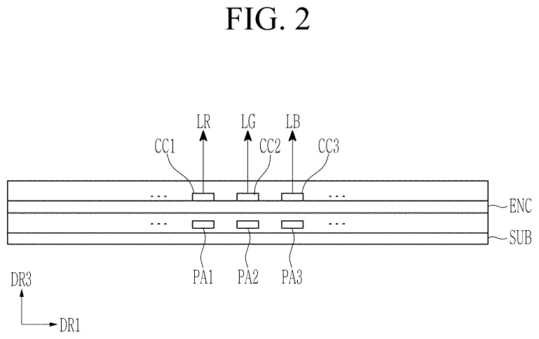

Hereinafter, a display area of a display panel according to some embodiments will be described with reference to FIG. 2. FIG. 2 illustrates a schematic cross-sectional view of a display panel according to some embodiments of the present disclosure.

Referring to FIG. 2, a plurality of pixels PA1, PA2, and PA3 may be disposed on a substrate SUB corresponding to the display area DA of FIG. 1. Each of the pixels PA1, PA2, and PA3 may include the plurality of transistors and a light emitting device connected thereto. Here, shapes and arrangements of the plurality of pixels PA1, PA2, and PA3 may be variously modified in a suitable manner.

An encapsulation layer ENC may be disposed on the plurality of pixels PA1, PA2, and PA3. The display area DA may be protected from external air or moisture through the encapsulation layer ENC. The encapsulation layer ENC may be integrally provided to overlap the entire display area DA, and may be partially disposed on the non-display area PA.

A first color conversion portion CC1, a second color conversion portion CC2, and a transmission portion CC3 may be disposed on the encapsulation layer ENC. The first color conversion portion CC1 may overlap the first pixel PA1, the second color conversion portion CC2 may overlap the second pixel PA2, and the transmission portion CC3 may overlap the third pixel PA3.

Light emitted from the first pixel PA1 may pass through the first color conversion portion CC1 to provide red light LR. Light emitted from the second pixel PA2 may pass through the second color conversion portion CC2 to provide green light LG. Light emitted from the third pixel PA3 may pass through the transmission portion CC3 to provide blue light LB.

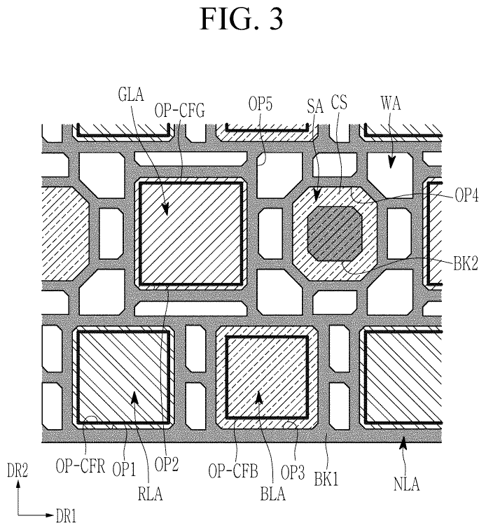

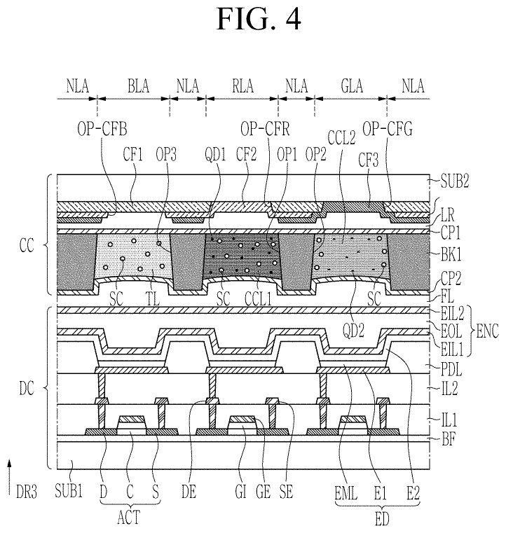

Hereinafter, a structure of a display panel according to some embodiments will be described in more detail with reference to FIGS. 3 to 6. FIG. 3 is a plan view of some pixels in a display panel according to some embodiments, and FIGS. 4 to 6 are respectively a cross-sectional view of a partial area of a display panel, according to some embodiments of the present disclosure.

First, referring to FIG. 3, a display area according to some embodiments includes a red-light emitting area RLA, a green-light emitting area GLA, and a blue-light emitting area BLA. A non-light emitting area NLA may be disposed between the red-light emitting area RLA, the green-light emitting area GLA, and the blue-light emitting area BLA. Each light emitting area may correspond to a pixel. For example, the blue-light emitting area BLA, the red-light emitting area RLA, and the green-light emitting area GLA may correspond to a blue pixel, a red pixel, and a green pixel, respectively.

According to some embodiments, each of the red-light emitting area RLA, the green-light emitting area GLA, and the blue-light emitting area BLA may have a quadrangular shape in a plan view, but is not limited thereto, and may have various suitable shapes such as a circular shape, an elliptical shape, a polygonal shape, and a polygonal shape having rounded corners.

In addition, the present specification illustrates some embodiments in which the planar area decreases in the order of the green-light emitting area GLA, the red-light emitting area RLA, and the blue-light emitting area BLA, but the order is not particularly limited and the area of each light emitting area may be variously modified in a suitable manner.

The display device according to some embodiments may include a spacer area SA and a well area WA.

The spacer area SA is an area in which a column spacer CS is disposed. The planar area of the spacer area SA may be substantially the same as the planar area of the blue-light emitting area BLA. In the present specification, “substantially the same” area may mean having an area of about 90% to about 110% based on the referenced area.

The well area WA according to some embodiments may be disposed between the red-light emitting area RLA, the green-light emitting area GLA, the blue-light emitting area BLA, and the spacer area SA, which are adjacent to each other. A plurality of well areas WA may surround each of the red-light emitting area RLA, the green-light emitting area GLA, the blue-light emitting area BLA, and the spacer area SA. However, the present disclosure is not limited thereto, and the shape and number of the well areas WA may be variously modified in a suitable manner.

Hereinafter, a cross-sectional structure of the display panel will be described with reference to FIGS. 3 and 4.

The display panel according to some embodiments includes a display portion DC and a color conversion portion CC disposed on the display portion DC.

The display portion DC includes a first substrate SUB1. The first substrate SUB1 may include a flexible material such as plastic that may be easily curved, bent, folded, or rolled.

A buffer layer BF may be disposed on the first substrate SUB1. In some embodiments, the buffer layer BF may be omitted. The buffer layer BF may include silicon nitride (SiNₓ), silicon oxide (SiO₂), silicon oxynitride, and/or the like. The buffer layer BF may block impurities from the first substrate SUB1 during the crystallization process for forming polycrystalline silicon, thereby improving the properties of the polycrystalline silicon. In addition, the buffer layer BF may planarize the first substrate SUB1 to relieve stress on a semiconductor layer ACT formed on the buffer layer BF.

The semiconductor layer ACT is disposed on the buffer layer BF. The semiconductor layer ACT may include polycrystalline silicon or an oxide semiconductor. The semiconductor layer ACT includes a channel region (C), a source region (S), and a drain region (D). The source region (S) and the drain region (D) are disposed on the respective sides of the channel region (C). The channel region (C) includes an intrinsic semiconductor that is undoped or substantially undoped with impurities, and the source region (S) and the drain region (D) include an impurity semiconductor that is doped with conductive impurities. The semiconductor layer ACT may be formed of an oxide semiconductor, and in some examples, a separate passivation layer may be added to protect oxide semiconductor material that is vulnerable to external environments such as high temperature.

A gate insulating film GI is disposed on the semiconductor layer ACT. The gate insulating film GI may be a single layer or multiple layers including at least one of silicon nitride (SiNₓ), silicon oxide (SiO₂), and silicon oxynitride.

A gate electrode GE is disposed on the gate insulating film GI, and the gate electrode GE may be a multilayer stacked metal film including one of copper (Cu), a copper alloy, aluminum (Al), an aluminum alloy, molybdenum (Mo), or a molybdenum alloy.

An interlayer insulating film IL1 is disposed on the gate electrode GE and the gate insulating film GI. The interlayer insulating film IL1 may include silicon nitride (SiNₓ), silicon oxide (SiO₂), silicon oxynitride, or the like. An opening exposing the source region (S) and the drain region (D) is disposed in the interlayer insulating film IL1.

The source electrode SE and the drain electrode DE are disposed on the interlayer insulating film IL1. The source electrode SE and the drain electrode DE are electrically connected to the source region (S) and the drain region (D) of the semiconductor layer ACT, respectively, through the opening formed in the interlayer insulating film IL1.

A passivation film IL2 is disposed on the interlayer insulating film IL1, the source electrode SE, and the drain electrode DE. The passivation film IL2 covers and planarizes the interlayer insulating film IL1, the source electrode SE, and the drain electrode DE, so that a first electrode E1 may be formed without a step on the passivation film IL2. The passivation film IL2 may be made of an organic material such as a polyacrylate resin and a polyimide resin, or a stacked film of organic and inorganic materials.

The first electrode E1 is disposed on the passivation film IL2. The first electrode E1 is connected to the drain electrode DE through an opening of the passivation film IL2.

The driving transistor configured of the gate electrode GE, the semiconductor layer ACT, the source electrode SE, and the drain electrode DE is connected to the first electrode E1 to supply a driving current to the light emitting element ED. In addition to the driving transistor shown in FIG. 4, the display device according to some embodiments may further include a switching transistor connected to a data line and for transmitting a data voltage in response to a scan signal, and a compensation transistor connected to the driving transistor and for compensating for a threshold voltage of the driving transistor in response to a scan signal.

A pixel defining film PDL is disposed on the passivation film IL2 and the first electrode E1. The pixel defining film PDL may overlap the first electrode E1 and have a pixel opening defining a light emitting area. The pixel opening may have a planar shape that is substantially similar to the first electrode E1, and may have a quadrangular, rhombic, or octagonal shape similar to a rhombus in a plan view, but is not limited thereto, and may have various suitable shapes such as a circle, an ellipse, and a polygon.

The pixel defining film PDL may include an organic material such as a polyacrylate resin or a polyimide resin, or a silica-based inorganic material.

A light emitting layer EML is disposed on the first electrode E1 that overlaps the pixel opening. The light emitting layer EML may be made of a low-molecular organic material or a high-molecular organic material such as PEDOT (poly 3,4-ethylenedioxythiophene). In addition, the light emitting layer EML may be a multifilm further including one or more of a hole injection layer (HIL), a hole transport layer (HTL), an electron transport layer (ETL), and an electron injection layer (EIL).

The light emitting layer EML may be mostly disposed within the pixel opening, and in some embodiments, it may also be disposed on the side or on the pixel defining film PDL.

A second electrode E2 is disposed on the light emitting layer EML. The second electrode E2 may be disposed throughout a plurality of pixels and may receive a common voltage through a common voltage transmission portion in the non-display area.

The first electrode E1, the light emitting layer EML, and the second electrode E2 may configure the light emitting element ED.

Here, the first electrode E1 may be an anode, which is a hole injection electrode, and the second electrode E2 may be a cathode, which is an electron injection electrode. However, embodiments of the present disclosure are not necessarily limited thereto, and a first electrode E1 may be a cathode and a second electrode E2 may be an anode, according to a driving method of the organic light emitting display device.

Holes and electrons are injected into the light emitting layer EML from the first electrode E1 and the second electrode E 2, respectively, and light is emitted when excitons in which the injected holes and electrons are combined enter a ground state from an excited state.

The light emitting element ED according to some embodiments may include a plurality of light emitting units. Each light emitting unit may include a light emitting layer. The light emitting element ED may be a light emitting element having a tandem structure. The plurality of light emitting layers may emit the same light or different light. For example, the light emitting element ED may emit light that is a mixture of green light and blue light, or may emit blue light.

The encapsulation layer ENC is disposed on the second electrode E2. The encapsulation layer ENC may cover not only the upper surface but also the side surface of the display layer including the light emitting element ED to seal the display layer.

Because the light emitting element is very vulnerable to moisture and oxygen, the encapsulation layer ENC seals the display layer to block the inflow of external moisture and oxygen. In some examples, the encapsulation layer ENC may include a plurality of layers, and may be formed as a composite film including both an inorganic film and an organic film. For example, the encapsulation layer ENC may be formed as a triple layer in which a first inorganic film EIL1, an organic film EOL, and a second inorganic film EIL2 are sequentially formed.

The color conversion portion CC is disposed on the encapsulation layer ENC.

The color conversion portion CC includes a second substrate SUB2 overlapping the first substrate SUB1. The second substrate SUB2 may include a flexible material such as plastic that may be easily curved, bent, folded, or rolled.

The color conversion portion CC includes a first color filter CF1, a second color filter CF2, and a third color filter CF3 disposed between the second substrate SUB2 and the display portion DC.

The first color filter CF1 may overlap the transmission layer TL. The first color filter CF1 may transmit blue light that has passed through the transmission layer TL, and may absorb light of the remaining wavelength, thereby increasing purity of blue light emitted to the outside of the display device. The first color filter CF1 may be a blue color filter.

The second color filter CF2 may overlap a first color conversion layer CCL1. The second color filter CF2 may transmit red light that has passed through the first color conversion layer CCL1, and may absorb light of the remaining wavelength, thereby increasing purity of red light emitted to the outside of the display device. The second color filter CF2 may be a red color filter.

The third color filter CF3 may overlap the second color conversion layer CCL2. The third color filter CF3 may transmit green light that has passed through a second color conversion layer CCL2, and may absorb light of the remaining wavelength, thereby increasing purity of green light emitted to the outside of the display device. The third color filter CF3 may be a green color filter.

At least two of the third color filter CF3, the second color filter CF2, and the first color filter CF1 may overlap in the non-light emitting area NLA to serve as a light blocking member. The non-light emitting area NLA may overlap the pixel defining film PDL of the display portion DC and a first partition wall BK1 of the color conversion portion CC.

A low-refractive index layer LR may be disposed between the color filters CF1, CF2, and CF3 and the display portion DC. For example, the low-refractive index layer LR may include an organic material or may include an inorganic material such as silicon nitride (SiNₓ), silicon oxide (SiO₂), silicon oxynitride, or the like. The low-refractive index layer LR may be a layer having a relatively low refractive index. Light emission efficiency may be increased by the low-refractive index layer LR.

A first capping layer CP1 may be disposed between the low-refractive index layer LR and the display portion DC. The first capping layer CP1 may include, for example, silicon nitride (SiNₓ), silicon oxide (SiO₂), silicon oxynitride, or the like. In some embodiments, the first capping layer CP1 may be omitted.

The color conversion portion CC may include the first partition wall BK1 disposed between the first capping layer CP1 and the display portion DC. The first partition wall BK1 may include a first opening OP1, a second opening OP2, and a third opening OP3. The sizes of the first opening OP1, the second opening OP2, and the third opening OP3 may be different or the same.

Referring to FIG. 3 FIG. 4, the size of the first opening OP1 of the first partition wall BK1 in the red-light emitting area RLA may be larger than the size of the red color filter opening OP-CFR defined by the first color filter CF1. In addition, the size of the second opening OP2 of the first partition wall BK1 in the green-light emitting area GLA may be larger than the size of the green color filter opening OP-CFG defined by the first color filter CF1. In addition, the size of the third opening OP3 of the first partition wall BK1 in the blue-light emitting area BLA may be larger than the size of the blue color filter opening OP-CFB defined by the second color filter CF2.

Referring back to FIG. 4, the first color conversion layer CCL1 may be disposed in the first opening OP1. The first color conversion layer CCL1 may convert the supplied light into red light. The first color conversion layer CCL1 may include first quantum dots QD1. The second color conversion layer CCL2 may be disposed within the second opening OP2. The second color conversion layer CCL2 may convert the supplied light into green light. The second color conversion layer CCL2 may include second quantum dots QD2. The transmission layer TL may be disposed within the third opening OP3. The transmission layer TL may emit incident light (i.e., may allow incident light to pass through).

Hereinafter, quantum dots including the first quantum dots QD1 and the second quantum dots QD2 will be described in further detail.

In some examples, the quantum dot (hereinafter also referred to as a semiconductor nanocrystal) may include a group II-VI compound, a group III-V compound, a group IV-VI compound, a group IV element or compound, a group I-III-VI compound, a group II-III-VI compound, a group I-II-IV-VI compound, or a combination thereof.

The group II-VI compound may be selected from a two-element compound selected from CdSe, CdTe, ZnS, ZnSe, ZnTe, ZnO, HgS, HgSe, HgTe, MgSe, MgS, and a mixture thereof; a three-element compound selected from AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a four-element compound selected from HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The group II-VI compound may further include a group III metal.

The group III-V compound may be selected from a two-element compound selected from GaN, GaP, GaAs, GaSb, AlN, AlP, AlAs, AlSb, InN, InP, InAs, InSb, and a mixture thereof; a three-element compound selected from GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and a mixture thereof; and a four-element compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and a mixture thereof. The group III-V compound may further include a group II metal (e.g., InZnP).

The group IV-VI compound may be selected from a two-element compound selected from SnS, SnSe, SnTe, PbS, PbSe, PbTe, and a mixture thereof; a three-element compound selected from SnSeS, SnSeTe, SnSTe, PbSeS, PbSeTe, PbSTe, SnPbS, SnPbSe, SnPbTe, and a mixture thereof; and a four-element compound selected from SnPbSSe, SnPbSeTe, SnPbSTe, and a mixture thereof.

The above group IV element or compound may be selected from a group consisting of a mono-element compound selected from the group consisting of Si, Ge, and a combination thereof; and a group consisting of a two-element compound selected from the group consisting of SiC, SiGe, and a combination thereof, but is not limited thereto.

The group I-III-VI compound includes, for example, CuInSe₂, CuInS₂, CuInGaSe, and CuInGaS, but is not limited thereto. The group I-II-IV-VI compound includes, for example, CuZnSnSe and CuZnSnS, but is not limited thereto. The group IV element or compound may be selected from a group consisting of a mono-element compound selected from the group consisting of Si, Ge, and a mixture thereof; and a group consisting of a two-element compound selected from the group consisting of SiC, SiGe, and a mixture thereof.

The group II-III-VI compound may be selected from ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and a combination thereof, but is not limited thereto.

The group I-II-IV-VI compound may be selected from CuZnSnSe and CuZnSnS, but is not limited thereto.

In some embodiments, the quantum dot may not include cadmium. The quantum dot may include a semiconductor nanocrystal based on a group III-V compound including indium and phosphorus. The group III-V compound may further include zinc. The quantum dot may include a semiconductor nanocrystal based on a group II-VI compound including a chalcogen element (e.g., sulfur, selenium, tellurium, or a combination thereof) and zinc.

In the quantum dot, the two-element compound, the ternary element compound, and/or the quaternary element compound, which are described above, may be present in particles at uniform concentrations, or they may be divided into states having partially different concentrations to be present in the same particle. In addition, one quantum dot may have a core/shell structure surrounding another quantum dot. An interface between the core and the shell may have a concentration gradient in which a concentration of elements of the shell decreases closer to its center.

In some embodiments, the quantum dot may have a core-shell structure that includes a core including the nanocrystal described above and a shell surrounding the core. The shell of the quantum dot may serve as a passivation layer for maintaining semiconductor properties and/or as a charging layer for applying electrophoretic properties to the quantum dot by preventing chemical denaturation of the core. The shell may be a single layer or a multilayer. An interface between the core and the shell may have a concentration gradient in which a concentration of elements of the shell decreases closer to its center. An example of the shell of the quantum dot includes a metal or nonmetal oxide, a semiconductor compound, or a combination thereof.

For example, the metal or non-metal oxide may be a two-element compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and the like, or a three-element compound such as MgAl₂O₄, CoFe₂O₄, NiFe₂O₄, CoMn₂O₄, and the like.

In addition, the semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like.

An interface between the core and the shell may have a concentration gradient in which a concentration of elements of the shell decreases closer to its center. In addition, the semiconductor nanocrystal may have a structure including one semiconductor nanocrystal core and a multi-layered shell surrounding the semiconductor nanocrystal core. In some embodiments, the multi-layered shell may have two or more layers—for example, two, three, four, five, or more layers. Two adjacent layers of the shell may have a single composition or different compositions. In the multi-layered shell, each layer may have a composition that varies along a radius of the shell.

The quantum dot may have a full width at half maximum (FWHM) of the light emitting wavelength spectrum that is equal to or less than about 45 nm, for example equal to or less than about 40 nm, or equal to or less than about 30 nm, and in this range, color purity or color reproducibility may be improved. In addition, because light emitted through the quantum dot is emitted in all directions, a viewing angle of light may be improved.

In the quantum dot, the shell material and the core material may have different energy bandgaps. For example, the energy bandgap of the shell material may be greater than that of the core material. In some other embodiments, the energy bandgap of the shell material may be smaller than that of the core material. The quantum dot may have a multi-layered shell. In the multi-layered shell, an energy bandgap of an outer layer thereof may be larger than that of an inner layer thereof (i.e., a layer closer to the core). In the multi-layered shell, the energy bandgap of the outer layer may be smaller than the energy bandgap of the inner layer.

The quantum dot may adjust an absorption/light emitting wavelength by adjusting a composition and size thereof. The maximum light emitting peak wavelength of the quantum dot may have a wavelength range from ultraviolet to infrared wavelengths or more.

The quantum dot may have a quantum efficiency of about 10% or more—for example, about 30% or more, about 50% or more, about 60% or more, about 70% or more, about 90% or more, or even 100%. The quantum dot may have a relatively narrow spectrum. The quantum dot may have a full width at half maximum of a light emitting wavelength spectrum of, for example, about 50 nm or less, about 45 nm or less, about 40 nm or less, or about 30 nm or less.

The quantum dot may have a particle size of about 1 nm or more and about 100 nm or less. The particle size refers to a particle diameter or a diameter converted by assuming a spherical shape from a 2-dimensional image obtained by transmission electron microscope analysis. The quantum dot may have a size of, for example, about 1 nm to about 20 nm, 2 nm or more, 3 nm or more, or 4 nm or more, 50 nm or less, 40 nm or less, 30 nm or less, 20 nm or less, 15 nm or less, or 10 nm or less. The shape of the quantum dot is not particularly limited. For example, the shape of the quantum dot may be a sphere, a polyhedron, a pyramid, a multi-pod, a square, a cuboid, a nanotube, a nanorod, a nanowire, a nanosheet, or a combination thereof, but is not limited thereto.

The quantum dot may be commercially available, or may be appropriately synthesized. The quantum dot may control the particle size relatively freely and uniformly during colloidal synthesis.

The quantum dot may include an organic ligand (e.g., having a hydrophobic moiety and/or a hydrophilic moiety). The organic ligand moiety may be bound to a surface of the quantum dot. The organic ligand may include RCOOH, RNH₂, R₂NH, R₃N, RSH, R₃PO, R₃P, ROH, RCOOR, RPO(OH)₂, RHPOOH, R₂POOH, or a combination thereof, wherein, R is independently a C3 to C40 substituted or unsubstituted aliphatic hydrocarbon group such as a C3 to C40 (e.g., C5 or greater and C24 or less) substituted or unsubstituted alkyl, or a substituted or unsubstituted alkenyl, a C6 to C40 (e.g., C6 or greater and C20 or less) substituted or unsubstituted aromatic hydrocarbon group such as a substituted or unsubstituted C6 to C40 aryl group, or a combination thereof.

Examples of the organic ligand may be a thiol compound such as methane thiol, ethane thiol, propane thiol, butane thiol, pentane thiol, hexane thiol, octane thiol, dodecane thiol, hexadecane thiol, octadecane thiol, or benzyl thiol; an amine such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, or trioctylamine; a carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, or benzoic acid; a phosphine compound such as methyl phosphine, ethyl phosphine, propyl phosphine, butyl phosphine, pentyl phosphine, octylphosphine, dioctyl phosphine, tributylphosphine, or trioctylphosphine; a phosphine compound or an oxide compound thereof such methyl phosphine oxide, ethyl phosphine oxide, propyl phosphine oxide, butyl phosphine oxide, pentyl phosphine oxide, tributylphosphine oxide, octylphosphine oxide, dioctyl phosphine oxide, or trioctylphosphine oxide; a diphenyl phosphine, a triphenyl phosphine compound, or an oxide compound thereof; a C5 to C20 alkyl phosphonic acid such as hexylphosphinic acid, octylphosphinic acid, dodecane phosphinic acid, tetradecane phosphinic acid, hexadecane phosphinic acid, octadecane phosphinic acid; and the like, but are not limited thereto. The quantum dot may include a hydrophobic organic ligand alone or may be in a mixture of at least one type. The hydrophobic organic ligand may not include a photopolymerizable moiety (e.g., an acrylate group, a methacrylate group, etc.).

The first color conversion layer CCL1, the second color conversion layer CCL2, and the transmission layer TL may include a scatterer SC. The scatterer SC may be one or more of SiO₂, BaSO₄, Al₂O₃, ZnO, ZrO₂, and TiO₂.

A second capping layer CP2 may be disposed between the first partition wall BK1, the first color conversion layer CCL1, the second color conversion layer CCL2, the transmission layer TL, and the display portion DC. The second capping layer CP2 may have a shape covering the first partition wall BK1, the first color conversion layer CCL1, the second color conversion layer CCL2, and the transmission layer TL. The second capping layer CP2 may include an inorganic material. The second capping layer CP2 may be omitted in some embodiments.

A filling layer FL may be disposed between the second capping layer CP2 and the display portion DC. The color conversion portion CC and the display portion DC may be combined by filling the space between the color conversion portion CC and the display portion DC with the filling layer FL.

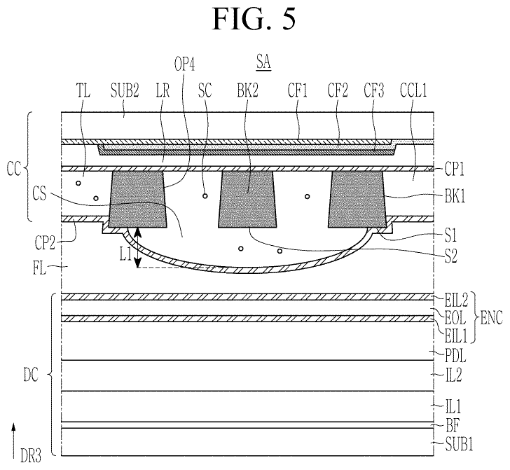

Hereinafter, a partial area of a display panel according to some embodiments will be described with reference to FIG. 3 and FIG. 5. FIG. 5 is a cross-sectional view of a spacer area.

Referring to FIG. 5, the display portion DC and the color conversion portion CC may be disposed in the spacer area SA. A filling layer FL may be disposed between the display portion DC and the color conversion portion CC.

The display portion DC overlapping the spacer area SA may include the first substrate SUB1, the buffer layer BF, the first insulating layer IL1, the second insulating layer IL2, the pixel defining layer PDL, the first encapsulation inorganic layer EIL1, the organic encapsulation layer EOL, and the second encapsulation inorganic layer EIL2 described above. However, the present disclosure is not limited thereto, and the components of the display portion DC described above may be disposed, or some of the components described above may be omitted.

The second substrate SUB2, the first color filter CF1, the second color filter CF2, and the third color filter CF3 described above may be sequentially disposed in the color conversion portion CC overlapping the spacer area SA. The first color filter CF1, the second color filter CF2, and the third color filter CF3 may overlap each other in the spacer area SA to serve as a light blocking layer. The present specification illustrates some embodiments in which the first color filter CF1, the second color filter CF2, and the third color filter CF3 are sequentially stacked on the second substrate SUB2 in the spacer area SA; however, the order of the overlapping color filters may be changed and is not limited thereto.

In the spacer area SA, the low-refractive index layer LR and the first capping layer CP1 may be sequentially disposed between the third color filter CF3 and the display portion DC. The first partition wall BK1 may be disposed between the first capping layer CP1 and the display portion DC.

The first partition wall BK1 may include a fourth opening OP4. The column spacer CS may be disposed in the fourth opening OP4.

The column spacer CS according to some embodiments may include the same or substantially the same material as the transmission layer TL described in FIG. 4. The column spacer CS may include the scatterer SC. The column spacer CS may be manufactured in the same process as the transmission layer TL.

The column spacer CS may have a convex shape toward the display portion DC. A straight-line distance L1 between one surface S1 of the first partition wall BK1 and the thickest portion of the column spacer CS may be about 3 micrometers to about 4 micrometers.

A second partition wall BK2 may be disposed within the fourth opening OP4. The second partition wall BK2 may be manufactured in the same process as the first partition wall BK1. The upper surface S1 of the first partition wall BK1 may have lyophobic properties, and the upper surface S2 of the second partition wall BK2 may have lyophilic properties. Both side surfaces of the first partition wall BK1 and the second partition wall BK2 may have lyophilic properties.

The first partition wall BK1 and the second partition wall BK2 may be substantially the same height, and in some embodiments, the height of the second partition wall BK2 may be slightly less than the height of the first partition wall BK1.

The column spacer CS may completely cover the upper surface S2 and the side surface of the second partition wall BK2. The column spacer CS may be in direct contact with the upper surface S2 and the side surface of the second partition wall BK2. Because the upper surface S2 of the second partition wall BK2 has lyophilic properties, the column spacer CS may be stably formed on the second partition wall BK2.

The column spacer CS may overlap at least a portion of the upper surface S1 of the first partition wall BK1. Because the upper surface S1 of the first partition wall BK1 has lyophobic properties, the ink dripped during the process of manufacturing the column spacer CS may not be disposed on the upper surface S1 of the first partition wall BK1. However, in some embodiments, the entire column spacer CS is not disposed only within the fourth opening OP4, but may partially overlap the upper surface S1 of the first partition wall BK1 as shown in FIG. 5. In addition, the column spacer CS may be in direct contact with the side surface of the first partition wall BK1. Because the side surface of the first partition wall BK1 has lyophilic properties, the column spacer CS may be stably disposed in the fourth opening OP4.

The second capping layer CP2 may be disposed between the first partition wall BK1 and the column spacer CS and the display portion DC. The filling layer FL may be disposed between the second capping layer CP2 and the display portion DC.

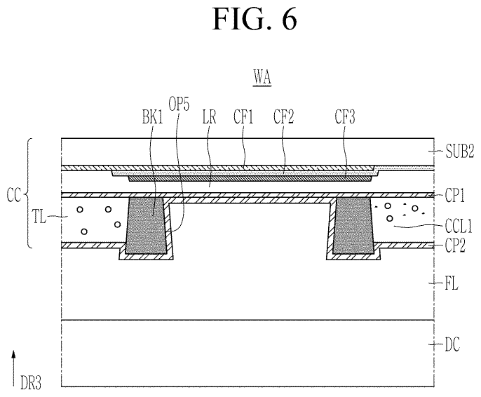

Hereinafter, the well area WA will be described with reference to FIGS. 3 and 6.

Referring to FIG. 6 together with FIG. 3, the display portion DC and the color conversion portion CC may be disposed in the well area WA. The display portion DC is not specifically shown, but it may have the same structure as the spacer area SA.

The first color filter CF1, the second color filter CF2, and the third color filter CF3 described above may be disposed in the color conversion portion CC overlapping the well area WA. The first color filter CF1, the second color filter CF2, and the third color filter CF3 may overlap each other in the well area WA to serve as a light blocking layer. The present specification illustrates some embodiments in which the first color filter CF1, the second color filter CF2, and the third color filter CF3 are sequentially stacked on the second substrate SUB2 in the well area WA, but is not limited thereto, and the order of the overlapping color filters may be changed.

In the well area WA, the low-refractive index layer LR and the first capping layer CP1 may be sequentially disposed between the third color filter CF3 and the display portion DC. The first partition wall BK1 may be disposed between the first capping layer CP1 and the display portion DC.

The first partition wall BK1 may include a fifth opening OP5. The fifth opening OP5 may not have a configuration disposed on the same layer as the color conversion layer CCL1 and the transmission layer TL. During the manufacturing process, the fifth opening OP5 may be provided as an empty space. In such examples, even if the ink for forming the color conversion layer CCL1 is misplaced beyond the first partition wall BK1, it may be injected into the fifth opening OP5 corresponding to the non-light emitting area. Similarly, even if the ink for forming the transmission layer TL is misplaced beyond the first partition wall BK1, it may be injected into the fifth opening OP5 corresponding to the light blocking area. Provision of the well area WA allows the stacked structure of the color conversion layer and the transmission layer to be formed stably.

In the well area WA, the second capping layer CP2 may be disposed in the fifth opening OP5. In the well area WA, the second capping layer CP2 may be disposed to be stepped along a side surface of the first partition wall BK1 and one surface of the exposed first capping layer CP1. In some areas, the first capping layer CP1 and the second capping layer CP2 may be in contact.

The filling layer FL may be disposed between the second capping layer CP2 and the display portion DC in the well area WA. The filling layer FL may fill the fifth opening OP5. The filling layer FL may be disposed within the fifth opening OP5.

According to some embodiments described with reference to FIGS. 3 to 6, the column spacer CS and the transmission layer TL are manufactured in the same process, so the time required for the process may be reduced. In addition, because the space in which the column spacer CS is disposed is not separately required, it may be easy to dispose the column spacer CS. Because the second partition wall is additionally disposed in the opening in which the column spacer CS is disposed, it may be easy to provide a convex column spacer toward the display portion DC.

The present specification illustrates one red-light emitting area, one green-light emitting area, one blue-light emitting area, and one spacer area. The spacer area may be disposed in each repeating unit including one red-light emitting area, one green-light emitting area, and one blue-light emitting area, or may be disposed only in one of a plurality of repeating units.

In addition, the present specification illustrates a plurality of well areas surrounding one red-light emitting area, one green-light emitting area, one blue-light emitting area, and one spacer area, but in some embodiments, the well area may be omitted.

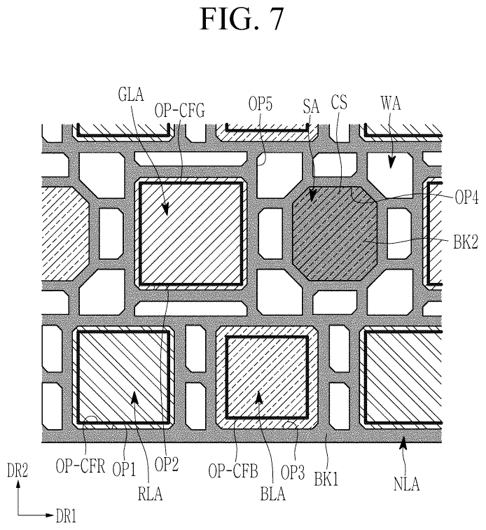

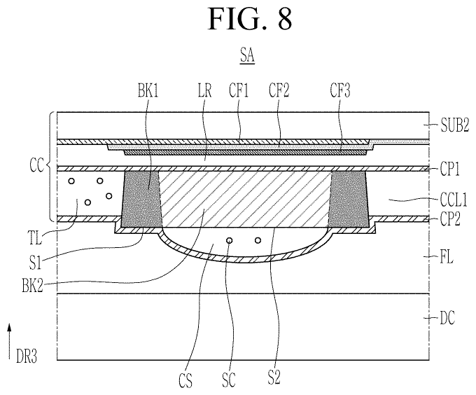

Hereinafter, a display panel according to some embodiments will be described with reference to FIGS. 7 and 8. FIG. 7 is a top plan view of a display panel according to some embodiments of the present disclosure, and FIG. 8 illustrates a cross-sectional view of a display panel according to some embodiments of the present disclosure.

First, referring to FIG. 7, a display device according to some embodiments may include a red-light emitting area RLA, a green-light emitting area GLA, a blue-light emitting area BLA, a spacer area SA, and a well area WA. The red-light emitting area RLA, the green-light emitting area GLA, the blue-light emitting area BLA, and the well area WA are the same as the components according to some embodiments of FIGS. 3 to 6, so hereinafter, the spacer area SA will be described.

Referring to FIGS. 7 and 8, the display portion DC and the color conversion portion CC may be disposed in the spacer area SA. A filling layer FL may be disposed between the display portion DC and the color conversion portion CC.

The first color filter CF1, the second color filter CF2, and the third color filter CF3 described above may be disposed in the color conversion portion CC overlapping the spacer area SA. The first color filter CF1, the second color filter CF2, and the third color filter CF3 may overlap each other in the spacer area SA to serve as a light blocking layer. The present specification illustrates some embodiments in which the first color filter CF1, the second color filter CF2, and the third color filter CF3 are sequentially stacked on the second substrate SUB2 in the spacer area SA, but is not limited thereto, and the order of the overlapping color filters may be changed.

In the spacer area SA, the low-refractive index layer LR and the first capping layer CP1 may be sequentially disposed between the third color filter CF3 and the display portion DC. The first partition wall BK1 may be disposed between the first capping layer CP1 and the display portion DC.

The second partition wall BK2 may be disposed in the spacer area SA. The second partition wall BK2 may be disposed between the first capping layer CP1 and the display portion DC. The second partition wall BK2 according to some embodiments may be integrally formed with the first partition wall BK1, and may be formed as one body. The first partition wall BK1 may surround the second partition wall BK2. The second partition wall BK2 may fill the fourth opening described above with reference to FIG. 5.

The second partition wall BK2 may be manufactured in the same process as the first partition wall BK1. One surface S1 of the first partition wall BK1 may have lyophobic properties, and one surface S2 of the second partition wall BK2 may have lyophilic properties. One surface S1 of the first partition wall BK1 and one surface S2 of the second partition wall BK2 may be substantially the same. In examples, some of the surfaces forming the same surface may have lyophilic properties, while others may have lyophobic properties.

The first partition wall BK1 and the second partition wall BK2 may be substantially the same height, and in some embodiments, the height of the second partition wall BK2 may be slightly less than the height of the first partition wall BK1.

The column spacer CS may be disposed on one surface S2 of the second partition wall BK2. The column spacer CS according to some embodiments may include the same or substantially the same material as the transmission layer TL described in FIG. 4. The column spacer CS may include the scatterer SC. The column spacer CS may be manufactured in the same process as the transmission layer TL.

The column spacer CS may have a convex shape toward the display portion DC. The straight-line distance between one surface S2 of the second partition wall BK2 and the thickest portion of the column spacer CS may be about 3 micrometers to about 4 micrometers.

Because one surface S2 of the second partition wall BK2 has lyophilic properties, the column spacer CS may be stably formed on the second partition wall BK2. On the other hand, because one surface S1 of the first partition wall BK1 has lyophobic properties, the ink for forming the column spacer CS may be hardly disposed on the first partition wall BK1.

The second capping layer CP2 may be disposed between the first partition wall BK1 and the column spacer CS and the display portion DC. The filling layer FL may be disposed between the second capping layer CP2 and the display portion DC.

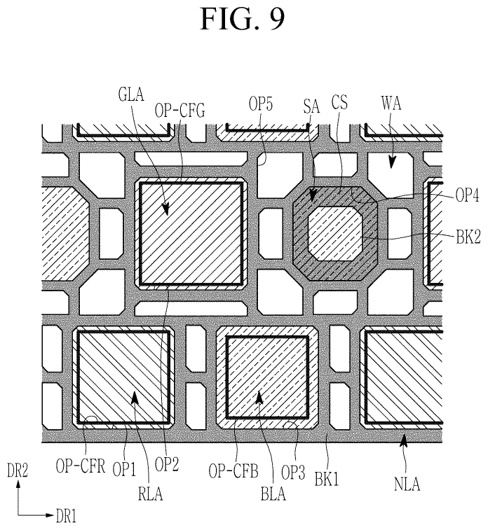

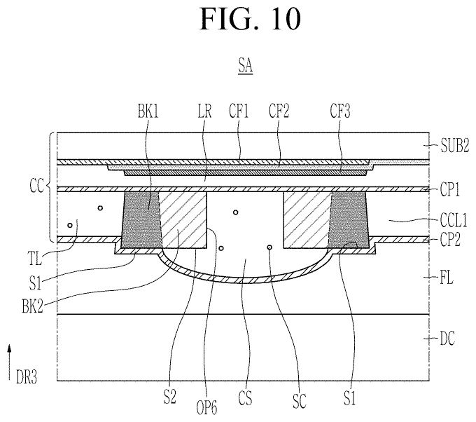

Hereinafter, a display panel according to some embodiments will be described with reference to FIGS. 9 and 10. FIG. 9 illustrates a top plan view of a display panel according to some embodiments, and FIG. 10 illustrates a cross-sectional view of a display panel according to some embodiments of the present disclosure.

First, referring to FIG. 9, a display device according to some embodiments may include a red-light emitting area RLA, a green-light emitting area GLA, a blue-light emitting area BLA, a spacer area SA, and a well area WA. The red-light emitting area RLA, the green-light emitting area GLA, the blue-light emitting area BLA, and the well area WA are the same as the components according to the embodiments of FIGS. 3 to 6, so hereinafter, the spacer area SA will be described.

Referring to FIGS. 9 and 10, the display portion DC and the color conversion portion CC may be disposed in the spacer area SA.

The first color filter CF1, the second color filter CF2, and the third color filter CF3 described above may be disposed in the color conversion portion CC overlapping the spacer area SA. The first color filter CF1, the second color filter CF2, and the third color filter CF3 may overlap each other in the spacer area SA to serve as a light blocking layer. The present specification illustrates some embodiments in which the first color filter CF1, the second color filter CF2, and the third color filter CF3 are sequentially stacked on the second substrate SUB2 in the spacer area SA, but is not limited thereto, and the order of the overlapping color filters may be changed.

In the spacer area SA, the low-refractive index layer LR and the first capping layer CP1 may be sequentially disposed between the third color filter CF3 and the display portion DC. The first partition wall BK1 may be disposed between the first capping layer CP1 and the display portion DC.

The second partition wall BK2 may be disposed in the spacer area SA. The second partition wall BK2 may be disposed between the first capping layer CP1 and the display portion DC. The second partition wall BK2 according to some embodiments may be integrally formed with the first partition wall BK1, and may be formed as one body. The first partition wall BK1 may surround the second partition wall BK2.

The second partition wall BK2 may be manufactured in the same process as the first partition wall BK1. One surface S1 of the first partition wall BK1 may have lyophobic properties, and one surface S2 of the second partition wall BK2 may have lyophilic properties. One surface S1 of the first partition wall BK1 and one surface S2 of the second partition wall BK2 may be substantially the same. In examples, some of the surfaces forming the same surface may have lyophilic properties, while others may have lyophobic properties.

The first partition wall BK1 and the second partition wall BK2 may be substantially the same height, and in some embodiments, the height of the second partition wall BK2 may be slightly less than the height of the first partition wall BK1.

The second partition wall BK2 may include a sixth opening OP6. The column spacer CS may be disposed in the sixth opening OP6. In addition, the column spacer CS may be disposed on one surface S2 of the second partition wall BK2. The column spacer CS according to some embodiments may include the same or substantially the same material as the transmission layer TL. The column spacer CS may include the scatterer SC. The column spacer CS may be manufactured in the same process as the transmission layer TL.

The column spacer CS may have a convex shape toward the display portion DC. The straight-line distance between one surface S2 of the second partition wall BK2 and the thickest portion of the column spacer CS may be about 3 micrometers to about 4 micrometers.

Because one surface S2 of the second partition wall BK2 has lyophilic properties, the column spacer CS may be stably formed on the second partition wall BK2. On the other hand, because one surface S1 of the first partition wall BK1 has lyophobic properties, the ink for forming the column spacer CS may be hardly disposed on the first partition wall BK1.

The second capping layer CP2 may be disposed between the first partition wall BK1 and the column spacer CS and the display portion DC. A filling layer FL may be disposed between the second capping layer CP2 and the display portion DC.

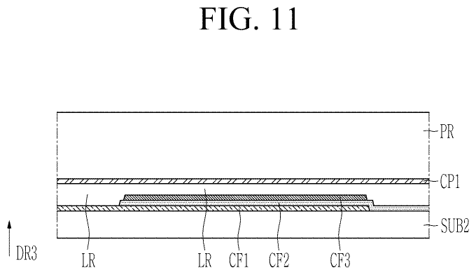

Hereinafter, a manufacturing method of a color conversion portion according to some embodiments will be described with reference to FIGS. 11 to 17. FIGS. 11 to 17 are cross-sectional views of a color conversion portion according to a manufacturing process of some embodiments of the present disclosure. Descriptions of the above-described components will be omitted.

Referring to FIG. 11, the first color filter CF1, the second color filter CF2, the third color filter CF3, the low-refractive index layer LR, and the first capping layer CP1 are sequentially formed on the second substrate SUB2. Then, a photosensitive resin composition PR is applied so as to overlap the entire surface of the second substrate SUB2.

The photosensitive resin composition PR according to some embodiments may include a fluorine (F) group. The fluorine (F) group may move to the top side of the photosensitive resin composition PR in the curing process. When cured from the top side, the fluorine group enables the partition wall to be lyophobic.

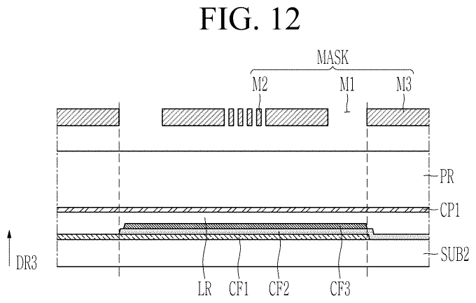

Next, referring to FIG. 12, a mask MASK is disposed on the photosensitive resin composition PR. The mask MASK is closed at a portion where the photosensitive resin composition PR is removed, and is open at a portion where the photosensitive resin composition PR is left. For example, the mask MASK has a completely opened shape in the first portion M1 in which the first partition wall is disposed. The mask MASK has a slit shape in the second portion M2 in which the second partition wall is disposed. In the remaining third portion M3, the mask MASK has a closed shape.

In such examples, the width between the slits in the second portion M2 may have a ratio of about 1:1. When the amount of light irradiated from the first portion M1 is 100%, the amount of light irradiated from the second portion M2 may be about 50%, and the amount of light irradiated from the third portion M3 may be 0%.

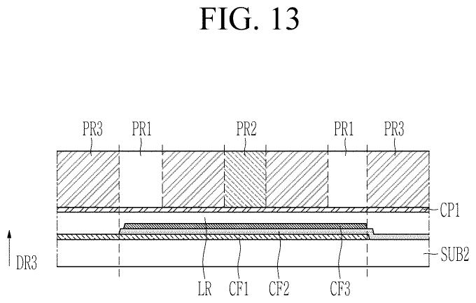

As shown in FIG. 13, the negative-type photosensitive resin composition PR1 may be completely cured in an area overlapping the first portion M1 of FIG. 12. In addition, the photosensitive resin composition PR3 overlapping the third portion M3 of FIG. 12 may not be cured at all. The photosensitive resin composition PR2 overlapping the second portion M2 of FIG. 12 may be partially cured.

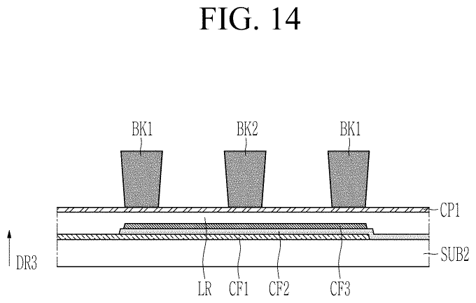

After the curing process, a developing process is performed. As shown in FIG. 14, the first partition wall BK1 and the second partition wall BK2 may be formed. In FIG. 13, the uncured photosensitive resin composition PR3 may be removed. In addition, in FIG. 13, the partially cured photosensitive resin composition PR2 may form the second partition wall BK2, as the fluorine group disposed on the top side thereof is removed. In FIG. 13, the completely cured photosensitive resin composition PR1 may form the first partition wall BK1.

In such examples, the first partition wall BK1 may include a fluorine group disposed on the top side of the first partition wall BK1. The upper surface of the first partition wall BK1 may have lyophobic properties. On the other hand, because the fluorine group disposed on the top side of the second partition wall BK2 is removed during the developing process, the upper surface of the second partition wall BK2 may have lyophilic properties.

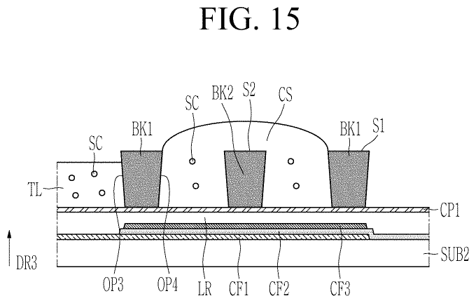

Next, as shown in FIG. 15, the transmission layer TL and the column spacer CS are formed in the same process. The transmission layer TL and the column spacer CS may include the scatterer SC. The transmission layer TL may be disposed within the third opening OP3, and the column spacer CS may be disposed within the fourth opening OP4.

Because one surface S1 of the first partition wall BK1 has lyophobic properties, the ink forming the transmission layer TL and the column spacer CS may be pushed toward the opening. On the other hand, because one surface S2 of the second partition wall BK2 has lyophilic properties, the ink forming the column spacer CS may be stably deposited within the opening.

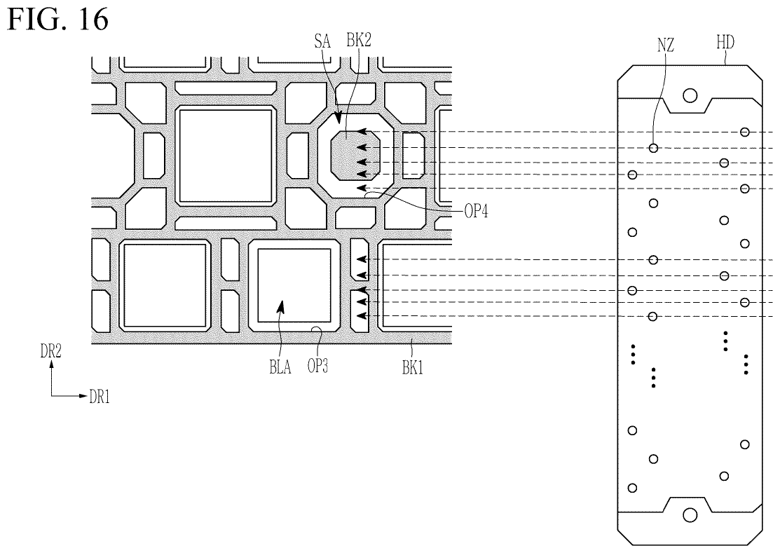

Referring to FIGS. 15 and 16, the transmission layer TL and the column spacer CS may be formed through an inkjet process. In such examples, ink may be supplied from an inkjet nozzle NZ overlapping the third opening OP3, and ink may be supplied from an inkjet nozzle NZ overlapping the fourth opening OP4. The planar sizes of the third opening OP3 and the fourth opening OP4 may be substantially the same. In such examples, a larger volume of ink may be utilized to provide a convex shape such as the column spacer CS.

However, because the second partition wall BK2 is disposed in the fourth opening OP4 according to some embodiments, the volume of the fourth opening OP4 may be reduced. The volume of ink required for the fourth opening OP4 may be reduced. Even if substantially the same number of inkjet nozzles are used in the third opening OP3 and the fourth opening OP4, a flat-shaped transmission layer TL may be formed in the third opening OP3, and a convex-shaped column spacer CS may be formed in the fourth opening OP4.

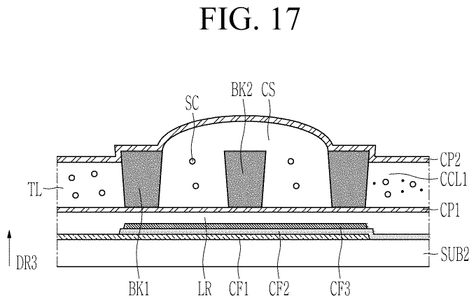

Then, as shown in FIG. 17, the first color conversion layer CCL1 may be formed using the inkjet process, and the second color conversion layer may be formed using the inkjet process. Then, the second capping layer CP2 disposed on the first partition wall BK1, the transmission layer TL, the column spacer CS, and the color conversion layer CCL1 may be formed.

Next, the display portion DC manufactured separately from the color conversion portion manufactured in FIG. 17 may be bonded to the color conversion portion to provide a display device having a structure such as that of FIGS. 3 to 6.

According to some embodiments, even when the planar area occupied by the transmission layer and the planar area occupied by the column spacer are similar, the volume of the ink for the column spacer for making a convex shape through the second partition wall may be reduced. It is possible to reduce the time required for the manufacturing process.

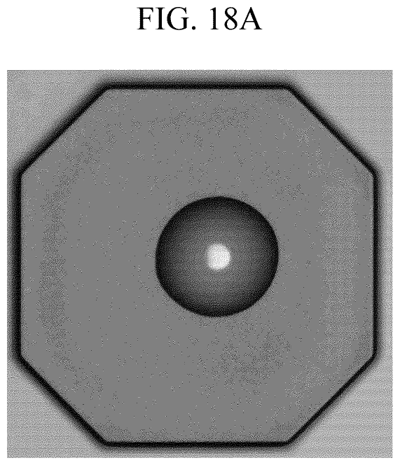

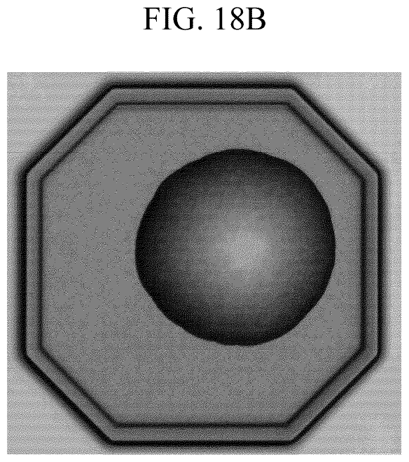

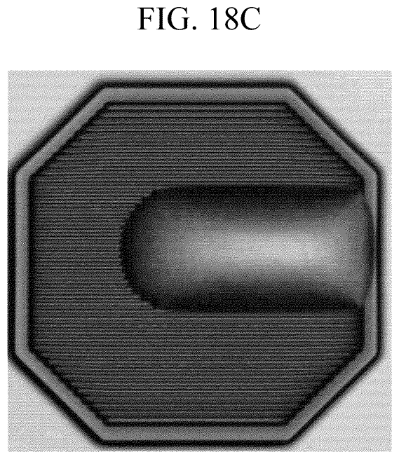

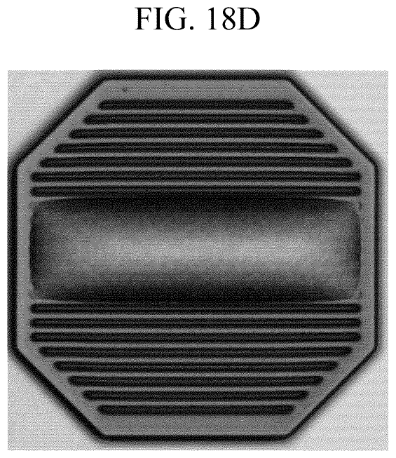

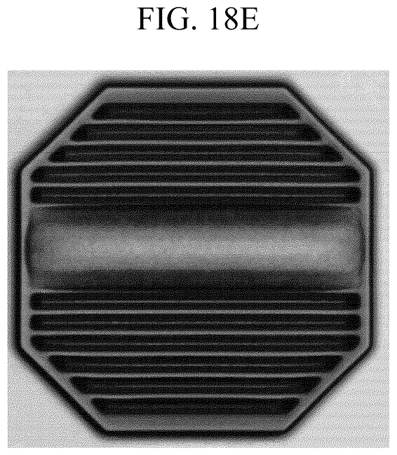

Hereinafter, the lyophobic properties according to examples and comparative examples will be described with reference to FIGS. 18A-18E. FIGS. 18A-18E are images of evaluation of liquid repellency according to changes in slit and spacer widths.

FIG. 18A is an image in which ink is dripped on the second partition wall exposed without a slit, and FIG. 18B is an image in which ink is dripped on the second partition wall manufactured using a mask having a slit width of 1 micrometer and a spacing between adjacent slits of 1 micrometer. FIG. 18C is an image in which ink is dripped on the second partition wall manufactured using a mask having a slit width of 2 micrometers and a spacing between adjacent slits of 1 micrometer. FIG. 18D is an image in which ink is dripped on the second partition wall manufactured using a mask having a slit width of 3 micrometers and a spacing between adjacent slits of 3 micrometers. FIG. 18E is an image in which ink is dripped on the second partition wall manufactured using a mask having a slit width of 6 micrometers and a spacing between adjacent slits of 3 micrometers. The number of slits included in the mask used in FIG. 18B is 43, the number of slits included in the mask used in FIG. 18C is 28, the number of slits included in the mask used in FIG. 18D is 14, and the number of slits included in the mask used in FIG. 18E is 9. When the amount of light irradiated in FIG. 18A is 100%, about 50% of the light may be irradiated when the slit masks of FIG. 18B and FIG. 18D are used. About 33% of the light may be irradiated when the slit masks of FIG. 18C and FIG. 18E are used.

As shown in FIG. 18A, the upper surface of the partition wall has lyophobic properties, so the dripped ink has a form in which it is collected. On the other hand, in the case of FIG. 18B, the upper surface of the partition wall becomes lyophilic, and the dripped ink has a spreading shape. In the case of FIG. 18C to FIG. 18E, the dripped ink has a spreading shape. However, in FIG. 18C to FIG. 18E, it was confirmed that the upper surface of the partition wall was patterned as the width of the slit increased. It was confirmed that the ink dripped by the upper surface of the patterned partition wall did not spread widely, but only spread sideways.

Accordingly, it was confirmed that the slit mask according to some embodiments had good ink spreadability because the lyophobic properties of the upper surface of the partition wall were eliminated when the width of the slit and the width between the slits were about 1 micrometer, and the upper surface of the partition wall was not patterned.

A display device according to some embodiments may be applied to various electronic devices. An electronic device according to some embodiments may include the display device, and may further include modules or devices having additional functions other than the display device.

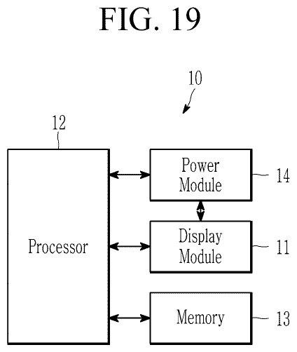

FIG. 19 is a block diagram of an electronic device according to some embodiments of the present disclosure. Referring to FIG. 19, the electronic device 10 according to some embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 10.

At least one of components of the electronic device 11 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 11 that are not part of the display device.

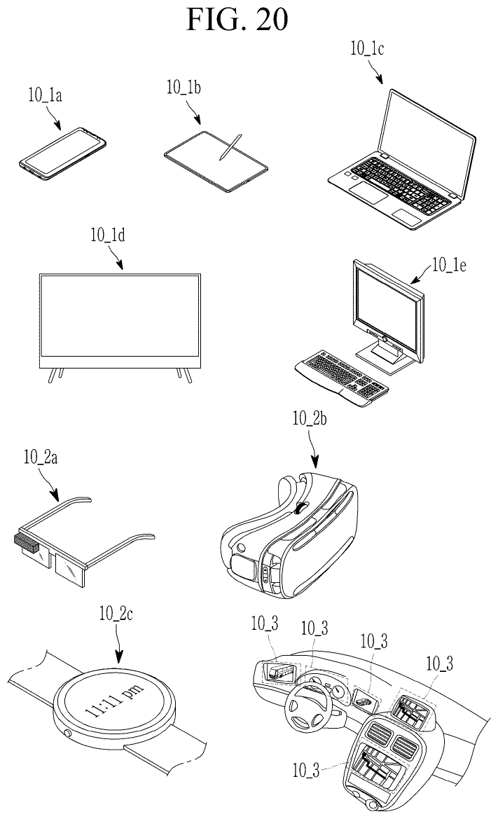

FIG. 20 illustrates schematic diagrams of electronic devices according to various embodiments of the present disclosure.

Referring to FIG. 20, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

While some embodiments of the present disclosure have been described in connection with what are presently considered to be practical embodiments, it is to be understood that the disclosure is not limited to the disclosed embodiments, but, on the contrary, is intended to cover various suitable modifications and equivalent arrangements included within the spirit and scope of preset disclosure, as defined by the appended claims and their equivalents.

### DESCRIPTION OF SOME OF THE REFERENCE SYMBOLS

SUB1: first substrate
ED: light emitting element
ENC: encapsulation layer
SUB2: second substrate
BK1: first partition wall
BK2: second partition wall
OP1, OP2, OP3, OP4, OP5, OP6: opening
CCL1: first color conversion layer
CCL2: second color conversion layer
CS: column spacer

What is claimed is:

1. A display device comprising:
a first substrate;
a transistor on the first substrate;
a light emitting element electrically connected to the transistor;
an encapsulation layer on the light emitting element;
a second substrate overlapping the first substrate;
a first partition wall between the encapsulation layer and the second substrate and having a first opening, a second opening, a third opening, and a fourth opening;
a first color conversion layer within the first opening;
a second color conversion layer within the second opening;
a transmission layer within the third opening;
a column spacer within the fourth opening; and
a second partition wall within the fourth opening,
wherein an upper surface of the first partition wall has lyophobic properties, and an upper surface of the second partition wall has lyophilic properties.

2. The display device of claim 1, wherein the second partition wall is surrounded by the first partition wall.

3. The display device of claim 1, wherein the column spacer is in direct contact with an upper surface and a side surface of the second partition wall.

4. The display device of claim 1, wherein the column spacer and the transmission layer comprise a same material.

5. The display device of claim 1, further comprising:
a first color filter overlapping the first color conversion layer;
a second color filter overlapping the second color conversion layer; and
a third color filter overlapping the transmission layer.

6. The display device of claim 5, wherein the column spacer overlaps the first color filter, the second color filter, and the third color filter.

7. The display device of claim 5, further comprising:
a low-refractive index layer between the first color filter and the first color conversion layer.

8. The display device of claim 5, further comprising:
a capping layer between the column spacer and the encapsulation layer; and
a filling layer between the capping layer and the encapsulation layer.

9. The display device of claim 8, wherein the first partition wall further comprises a fifth opening, and
wherein the fifth opening is filled with the filling layer.

10. The display device of claim 9, wherein in the fifth opening, the capping layer is in direct contact with a side surface of the first partition wall.

11. A display device comprising:
a first substrate;
a transistor on the first substrate;
a light emitting element electrically connected to the transistor;
an encapsulation layer on the light emitting element;
a second substrate overlapping the first substrate;
a first partition wall between the encapsulation layer and the second substrate and having a first opening, a second opening, a third opening, and a fourth opening;
a first color conversion layer within the first opening;
a second color conversion layer within the second opening;
a transmission layer within the third opening;
a second partition wall integrally formed with the first partition wall; and
a column spacer on the second partition wall,
wherein an upper surface of the first partition wall has lyophobic properties, and an upper surface of the second partition wall has lyophilic properties.

12. The display device of claim 11, wherein the second partition wall is surrounded by the first partition wall.

13. The display device of claim 11, wherein the column spacer and the transmission layer comprise a same material.

14. The display device of claim 11, further comprising:
a first color filter overlapping the first color conversion layer;
a second color filter overlapping the second color conversion layer; and
a third color filter overlapping the transmission layer,
wherein the column spacer overlaps the first color filter, the second color filter, and the third color filter.

15. A electronic device comprising:
a first substrate;
a transistor on the first substrate;
a light emitting element electrically connected to the transistor;
an encapsulation layer on the light emitting element;
a second substrate overlapping the first substrate;
a first partition wall between the encapsulation layer and the second substrate and having a first opening, a second opening, and a third opening;
a first color conversion layer within the first opening;
a second color conversion layer within the second opening;
a transmission layer within the third opening;
a second partition wall integrally formed with the first partition wall and having a fifth opening; and
a column spacer within the fifth opening,
wherein an upper surface of the first partition wall has lyophobic properties, and an upper surface of the second partition wall has lyophilic properties.

16. The electronic device of claim 15, wherein the second partition wall is surrounded by the first partition wall.

17. The electronic device of claim 15, wherein the column spacer and the transmission layer comprise a same material.

18. The electronic device of claim 15, further comprising:
a first color filter overlapping the first color conversion layer;
a second color filter overlapping the second color conversion layer; and
a third color filter overlapping the transmission layer,
wherein the column spacer overlaps the first color filter, the second color filter, and the third color filter.

19. The electronic device of claim 15, wherein a content of fluorine groups comprised in the upper surface of the first partition wall is greater than a content of fluorine groups comprised in the upper surface of the second partition wall.

20. The electronic device of claim 15, wherein a height of the first partition wall and a height of the second partition wall are the same.
